(19) United States
(12) Patent Application Publication
(10) Pub. No.: US 2015/0327377 A1
(43) Pub. Date: Nov. 12, 2015

(54) IMAGING DEVICE

(71) Applicant: SMK Corporation, Tokyo (JP)

(72) Inventors: Nobyuki MANO, Tokyo (JP); Taku AKAIWA, Kanagawa (JP)

(21) Appl. No.: 14/667,610

(22) Filed: Mar. 24, 2015

(30) Foreign Application Priority Data
May 8, 2014 (JP) 2014-96779

(51) Int. Cl. H05K 5/00; H05K 5/03

(52) U.S. Cl. CPC H05K 5/0069; H05K 5/03

(57) ABSTRACT

An imaging device includes: an electronic circuit unit that includes an imaging element and a first connection terminal; a case that accommodates the electronic circuit unit and has an opening so as to expose the first connection terminal therefrom; a lid-shaped body that causes a second connection terminal to be connected to the first connection terminal when the lid-shaped body abuts against the case. The lid-shaped body is loose-fitted in a moveable manner with respect to the case in a direction of an abutting surface that is substantially orthogonal to center axes of the first connection terminal and the second connection terminal. The lid-shaped body is fixed at an arbitrary position within a movable range with respect to the case in the abutting surface direction in a state in which the center axes of the first connection terminal and the second connection terminal are substantially aligned with each other.

### CROSS REFERENCE TO RELATED APPLICATION

The contents of the following Japanese patent application are incorporated herein by reference,

NO. 2014-96779 filed on May 8, 2014.

### FIELD

The present invention relates to an imaging device, and particularly, to an imaging device suitable for an in-vehicle camera, etc.

### BACKGROUND

In recent years, imaging devices have been widely used in a moving body, such as a vehicle, to support driving or to secure safety. In this type of imaging device, there are demands for reducing its installation space and installation weight. Further, as performance requirements for the imaging device become more advanced, a faster image transmission speed is required and a frequency of an image transmission signal, etc. is getting higher.

As a conventional imaging device, for example, an imaging device has been known that aims to stabilize an electrical connection state inside a case. This can be achieved, for example, by providing a structure in which an electronic circuit unit, which includes an imaging element and a female terminal, is accommodated inside a front case and the female terminal is exposed from a rear-side opening of the front case, while a plurality of male terminals are inserted and installed in a rear case in advance so as to have the male terminals and the female terminal fitted together when the rear-side opening of the front case is closed by the rear case (refer to Patent Literature 1, for example).

Further, another imaging device has been known that aims to secure a shielding performance. This can be achieved by providing a structure in which an electronic circuit unit, which includes an imaging element and a connector member, is accommodated inside a case in a state in which the electronic circuit unit is surrounded by an electrically conductive shielding case, and the shielding case is electrically connected to a reference potential of the electronic circuit unit or to a ground level (refer to Patent Literature 2, for example).

### CITATION LIST

### Patent Literature

Patent Literature 1: Japanese Patent Application Laid-Open No. 2013-210480.
Patent Literature 2: Japanese Patent Application Laid-Open No. 2011-259101.

### SUMMARY

### Technical Problem

However, when a frequency of an image transmission signal is made higher in response to an advance in performance requirements in the above-described imaging devices, a problem arises in which it becomes difficult to efficiently transmit an image transmission signal without loss relating to an external radio wave or noise.

In response to the problem, for example, it is possible to consider using a coaxial cable to form a transmission path for an image signal and connecting an imaging device with the cable, which forms the transmission path, using a coaxial connector. However, in this case, it is necessary to achieve the connection using a small coaxial connector with respect to a small imaging device. Then, a mechanical connection strength of the connection by the coaxial connector may be weakened or the connection may become a snap-on connection. As a result, when a vibration or a shock is applied depending on a usage environment, a mechanical connection structure is required to maintain a connection state of the coaxial connector.

However, when such a small connector and a mechanical connection structure of peripheral parts, which support the male and female connector members, are used in combination, it becomes difficult to connect the peripheral parts with one another without varying electrical connection states of small-sized male and female connector members (contact pressures of male and female central conductors, coaxiality, etc.). As a result, there is a possibility that an image transmission signal is not able to be transmitted efficiently, even when a connector that is highly resistant to an external radio wave or noise is used.

The present invention has been made to solve the above-described conventional problem, and it is an object of the present invention to provide a small and high performance imaging device that is capable of efficiently transmitting an image transmission signal without loss relating to an external radio wave or noise.

### Solution to Problem

To achieve the above-described object, an imaging device according to the present invention includes: an electronic circuit unit that includes an imaging element and a first connection terminal; a case that has a concave portion for accommodating the electronic circuit unit and an opening for allowing the first connection terminal to be exposed therefrom; a lid-shaped body that is formed in a lid-like shape so as to close the opening, the lid-shaped body integrally retaining a second connection terminal that is to be connected to the first connection terminal and causing the second connection terminal to be connected to the first connection terminal when the lid-shaped body abuts against the case so as to close the opening; and a fixing mechanism that fixes the lid-shaped body to the case in a state in which the opening is closed by the lid-shaped body. The lid-shaped body is loose-fitted in a movable manner to the case in a direction of an abutting surface that is substantially orthogonal to center axes of the first connection terminal and the second connection terminal. Further, the lid-shaped body is fixed at an arbitrary position within a movable range with respect to the case in the abutting surface direction in a state in which the center axes of the first connection terminal and the second connection terminal are substantially aligned with each other.

In the present invention with this configuration, when the lid-shaped body is loose-fitted in the movable manner to the case in the abutting surface direction, the second connection terminal is connected to the first connection terminal. As a result of this, the lid-shaped body and the second connection terminal are positioned in the abutting surface direction so that a good conductive contact state of the second connection terminal is obtained with respect to the first connection terminal that is accommodated in the case. As a result, an imaging device is obtained that is capable of efficiently transmitting an image transmission signal without loss relating to an external radio wave or noise.

In the imaging device according to the present invention, the first connection terminal and the second connection terminal may be formed by male and female conductors of a coaxial connector, respectively.

With this configuration, an image transmission signal can be efficiently transmitted without loss relating to an external radio wave or noise, even when the image transmission signal has a high frequency.

The fixing mechanism may include a bracket that can apply a pressing force so as to press the lid-shaped body against the case and a fastening member that fastens and fixes the bracket to the case. The bracket may have a plurality of protruding portions that are each locally pressed against, and in contact with, the case when the bracket is fastened and fixed to the case by the fastening member.

With this configuration, when the bracket of the fixing mechanism is fastened and fixed to the case by the fastening member in a state in which the bracket can apply a pressing force so as to press the lid-shaped body against the case, the bracket is fixed at an arbitrary position within the movable range with respect to the case in the abutting surface direction as a result of the plurality of protruding portions of the bracket each being locally pressed against, and in contact with, the case. Therefore, it becomes difficult for the bracket to be horizontally displaced or rotated with respect to the case when the bracket is fastened and fixed. Further, only the pressing force, which presses the lid-shaped body against the case, is effectively transmitted from the bracket to the lid-shaped body. Thus, obstruction of a good contact state of the second connection terminal to the first connection terminal as a result of horizontal displacement of the lid-shaped body is effectively removed. As a result, a small and high performance imaging device is obtained that is capable of efficiently transmitting an image transmission signal without loss relating to an external radio wave or noise.

Further, in the imaging device according to the present invention, the bracket may include a bracket main body that is loose-fitted in a movable manner with respect to the lid-shaped body in the abutting surface direction and a plurality of local pressure contact portions that are locally pressed against, and in contact with, the lid-shaped body when the bracket is fastened and fixed to the case by the fastening member.

With this configuration, when the bracket is fastened and fixed to the case by the fastening member, the lid-shaped body is fixed at an arbitrary position within the movable range in the abutting surface direction as a result of the plurality of local pressure contact portions of the bracket each being locally pressed against, and in contact with, the lid-shaped body. Note that, in that case, the plurality of local pressure contact portions of the bracket may preferably be pressed against, and in contact with, the lid-shaped body after the plurality of protruding portions of the bracket are pressed against, and in contact with, the case by a contact pressure equal to or greater than a predetermined surface pressure and also after the bracket is substantially fixed in the abutting surface direction.

Further, in the imaging device according to the present invention, the fastening member may be formed by a plurality of male screws that are screwed to a plurality of female screw portions provided in the case, and the bracket may have a plurality of washer-shaped portions through which the male screws penetrate.

With this configuration, it becomes difficult for the bracket to be horizontally displaced or rotated due to a fastening operation of the respective male screws, and obstruction of a good contact state of the second connection terminal to the first connection terminal as a result of horizontal displacement of the bracket is effectively removed.

According to the present invention, it is possible to provide a small and high performance imaging device that is capable of efficiently transmitting an image transmission signal without loss relating to an external radio wave or noise.

### BRIEF DESCRIPTION OF DRAWINGS

FIG. 1 is a cross-sectional view schematically illustrating an entire configuration of an imaging device according to one embodiment of the present invention.

FIG. 2 is an external perspective view of a rear side of essential parts of the imaging device according to the embodiment of the present invention.

FIG. 3A is a rear view illustrating the essential parts of the imaging device according to the embodiment of the present invention.

FIG. 3B is a side view illustrating the essential parts of the imaging device according to the embodiment of the present invention.

FIG. 4A is a cross-sectional view as viewed in a direction of arrows IVA-IVA shown in FIG. 3B.

FIG. 4B is a cross-sectional view as viewed in a direction of arrows IVB-IVB shown in FIG. 3B.

FIG. 5A is a rear view of the imaging device according to the embodiment of the present invention, illustrating a state in which a fastening member and a bracket, which are provided on a rear side of the imaging device shown in FIG. 2, are removed.

FIG. 5B is a rear view of a case that accommodates an electronic circuit unit provided with an imaging element, the case being in a state before being closed by a lid-shaped body in the imaging device according to the embodiment of the present invention.

FIG. 6 is an enlarged partial perspective view of a portion at which the lid-shaped body and a rear-side portion of the case are loose-fitted with each other, as viewed from the inside of the case in a state before being closed by the lid-shaped body in the imaging device according to the embodiment of the present invention.

FIG. 7 is an external perspective view of a front side of the imaging device according to the embodiment of the present invention.

FIG. 8 is an exploded perspective view of an internal assembly of the imaging device according to the embodiment of the present invention.

FIG. 9 is an exploded perspective view as viewed from a side of the front side of the imaging device according to the embodiment of the present invention.

FIG. 10 is an exploded perspective view as viewed from a side of the rear side of the imaging device according to the embodiment of the present invention.

FIG. 11 is an enlarged partial perspective view showing a mounted state of the bracket in the imaging device according to the embodiment of the present invention.

### DESCRIPTION OF EMBODIMENTS

An embodiment of the present invention will be described below with reference to the appended drawings.

### Embodiment

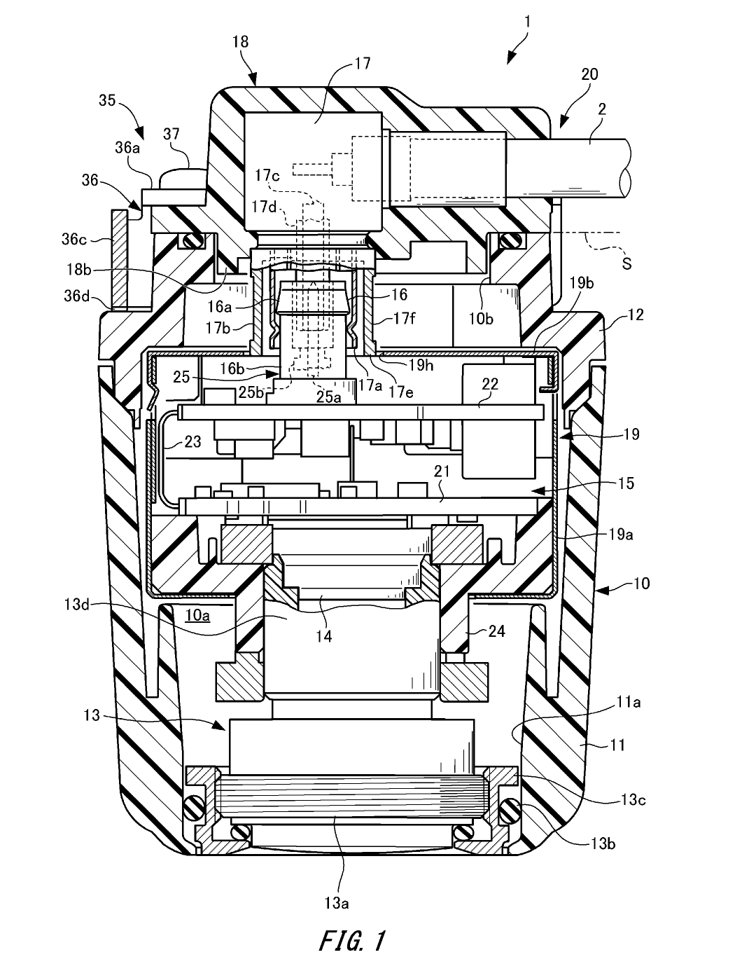

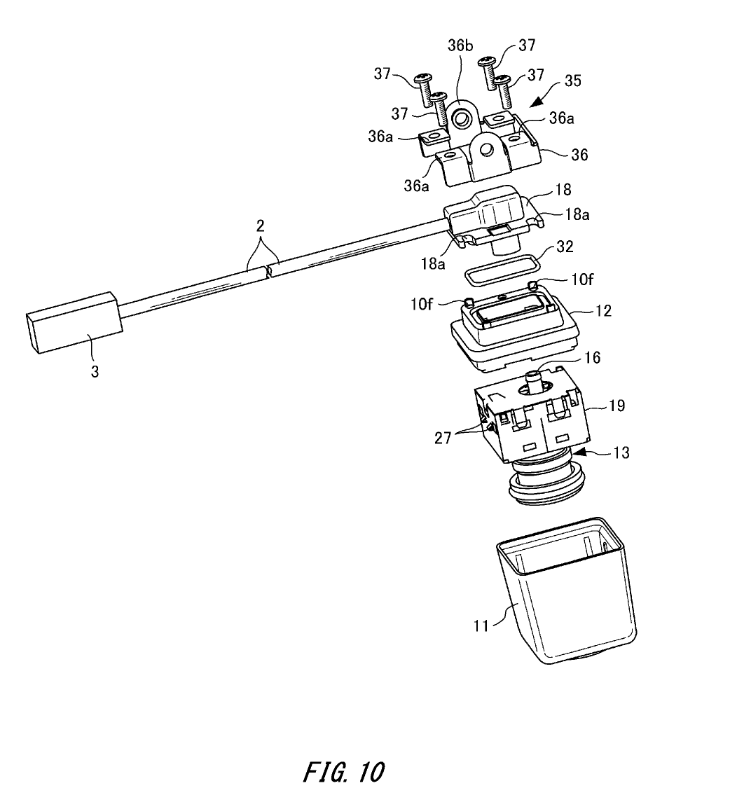

FIG. 1 to FIG. 11 are diagrams illustrating an imaging device according to one embodiment of the present invention.

Note that the imaging device according to this embodiment is formed as a camera unit that is mounted on a vehicle, and is used as part of an in-vehicle camera network system, which, for example, includes other in-vehicle camera units, a monitor, etc. Needless to say, the imaging device according to the present invention can be mounted on an object other than a vehicle.

First, a configuration of the imaging device according to this embodiment will be described.

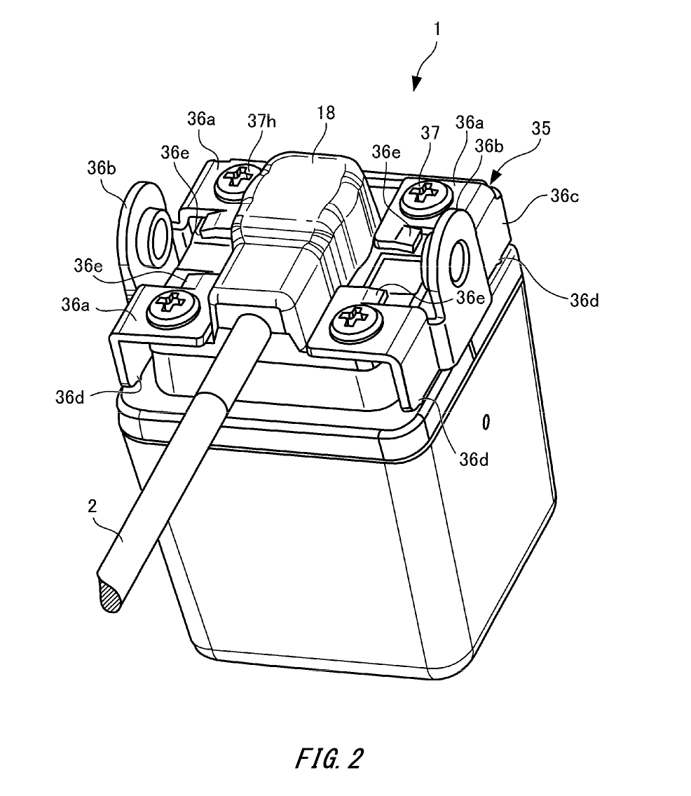

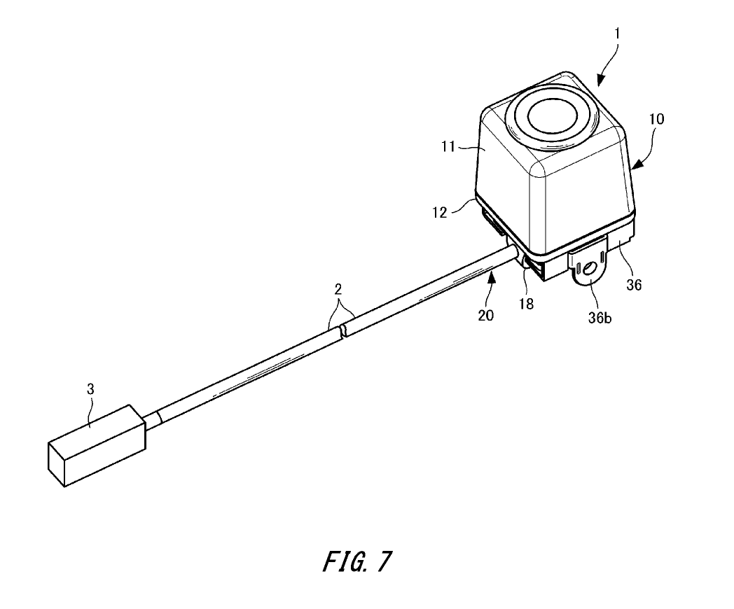

As illustrated in FIG. 1, FIG. 2, and FIG. 7, the imaging device according to this embodiment has an imaging device main body 1, a connection cable 2, and a connector 3.

The imaging device main body 1 is of a power supply superposition type that is supplied with power from an external electronic circuit, which includes a camera power source, via the connection cable 2 and the connector 3, and is capable of transmitting information of a captured image to the external electronic circuit via the connection cable 2 and the connector 3. Note that, since it is conventionally known that an imaging device of the power supply superposition type is used (refer to Japanese Patent Application Laid-Open No. Hei 5-304630 (1993-304630), for example), a detailed description regarding this point will be omitted herein.

The connection cable 2 has a small coaxial connector plug at one end located on the imaging device main body 1 side. The small coaxial connector plug may be a small plug of an SMB (Sub Miniature B) type, which is specified under the Military Standard (MIL) or Japanese Industrial Standards (JIS), or a small plug of a similar type (a second connection terminal 17 described below), for example. The connection cable 2 is formed by a thin coaxial cable that is compatible with the SMB type coaxial connector. The plug arranged at one end of the connection cable 2 is snap-locked to a receptacle (or a jack) of the SMB type coaxial connector, which is integrated in the imaging device main body 1, or is connected to an alternative receptacle that can make a snap-on connection (a first connection terminal 16 of a receptacle 25 described below). When a frequency of an image transmission signal is made higher to increase a transmission speed, it is preferable that a coaxial cable and a coaxial connector be used, as described in this embodiment.

The connector 3 is formed by an SMB type coaxial connector plug or a connector plug that converts the SMB type into another connector type, for example. The connector 3 is detachably connected to a receptacle or a connection terminal that is provided on a side of the above-described external electronic circuit, with the receptacle or the connection terminal being compatible with the connector 3.

As illustrated in FIG. 1, the imaging device main body 1 includes a front case 11 and a rear case 12, an imaging optical unit 13, an imaging element 14, an electronic circuit unit 15, a first connection terminal 16, a second connection terminal 17, a lid-shaped body 18, and a shielding case 19.

More specifically, the front case 11 and the rear case 12 are each made of a resin and form a case 10 that has a concave portion 10a that accommodates the imaging optical unit 13 and the electronic circuit unit 15, and an opening 10b thereinside, from which the first connection terminal 16 is exposed.

In the imaging optical unit 13, an imaging optical system is formed by a plurality of lenses, which are not shown in the drawings. The imaging optical unit 13 is concentrically accommodated inside the front case 11, of which the inner diameter becomes smaller toward the front side thereof. The front case 11 has a taper hole 11a that has a circular cross section and that is gently inclined toward a top end side thereof, the top end side accommodating the imaging optical unit 13. A top end portion 13a of the imaging optical unit 13 is concentrically positioned inside the taper hole 11a via an O-ring 13b and an installation ring 13c.

The electronic circuit unit 15 is configured by wiring and connecting a first circuit board 21, on which the imaging element 14 (such as a CCD (Charge Coupled Device) and the like) is mounted, and a second circuit board 22, on which the first connection terminal 16 is mounted, using an FPC (Flexible Printed Circuit) 23. More specifically, the electronic circuit unit 15 is configured to include the imaging element 14 and the first connection terminal 16.

Although details are not illustrated in the drawings, each of the first circuit board 21 and the second circuit board 22 of the electronic circuit unit 15 may include a plurality of electronic parts mounted thereon. The plurality of electronic parts, for example, constitute a synchronization signal generating circuit that drives the imaging element 14, a sample and hold circuit that samples and holds a signal from the imaging element 14, converts the signal into an image signal, and then amplifies and outputs the image signal, a gain regulator circuit, a process circuit, an amplifier circuit, etc.

Further, a substantially annular positioning member 24 is provided near the imaging element 14 of the first circuit board 21. The positioning member 24 supports the first circuit board 21 from a front side and is fitted with a rear end portion 13d of the imaging optical unit 13 so as to be able to abut against the rear end portion 13d in an axial direction. As a result, the imaging optical unit 13 and the imaging element 14 are accommodated inside the case 10 so as to be positioned on a same optical axis (an optical center axis).

The first connection terminal 16 and the second connection terminal 17 are formed by male and female conductors of the coaxial connector, respectively, wherein the male and female connectors are fitted with each other so as to be conductively connected. More specifically, the first connection terminal 16 forms an outer conductor of a snap-on connection type receptacle 25. The receptacle 25 is similar to a jack or a plug of the SMB type coaxial connector, for example, the jack or the plug being integrated in the imaging device main body 1. As illustrated in FIG. 1, the first connection terminal 16 does not have a normal annular groove for a snap-lock, but has a taper portion 16a for a snap-on connection on a top end side thereof and a straight portion 16b on a substrate side thereof. The taper portion 16a has a diameter that becomes smaller toward the top end of the first connection terminal 16 and obtains a maximum diameter at a position distanced by a predetermined distance from the top end. The straight portion 16b has a smaller diameter than that of the taper portion 16a.

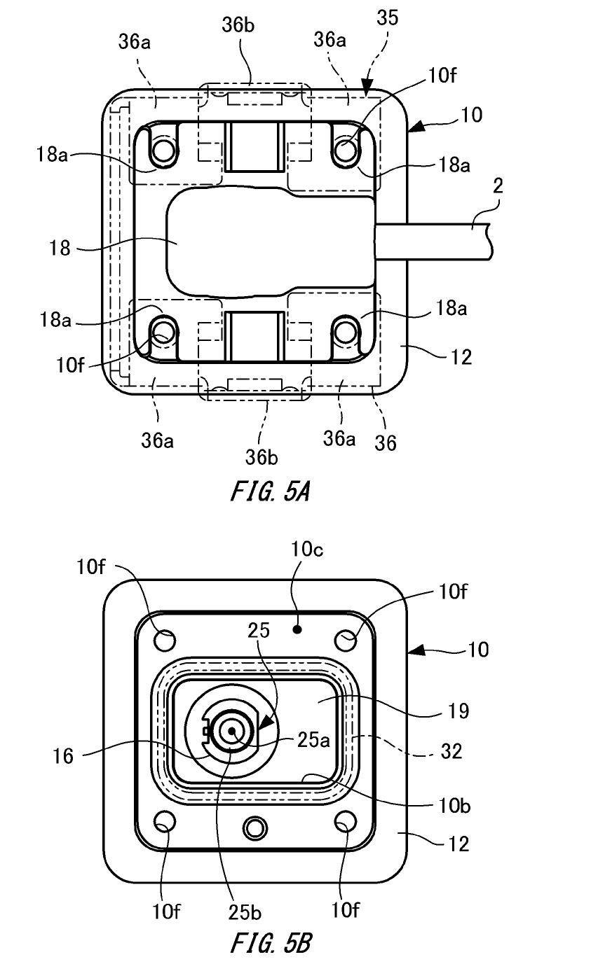

Note that, although a detailed internal structure of the first connection terminal 16 is not described herein as the internal structure may be similar to that of a conventional SMB type, as illustrated in FIG. 1, FIG. 5A and FIG. 5B, the receptacle 25 has a central conductor 25a, a tubular insulator 25b that surrounds a main portion of the central conductor 25a, and the first connection terminal 16 that functions as a tubular outer conductor that surrounds the insulator 25b while being separated from the central conductor 25a in a radial direction, for example. In addition, a tubular concave portion is formed inside the receptacle 25. Further, the first connection terminal 16 is connected to a ground pattern portion of the second circuit board 22.

The second connection terminal 17 is a plug or a jack of the SMB type coaxial connector, and the plug or the jack is provided on one end side of the above-described connection cable 2. The second connection terminal 17 can be snap-locked at a specific position in the axial direction with respect to a normal SMB type receptacle. However, the second connection terminal 17 is not snap-locked at the specific position in the axial direction with respect to the first connection terminal 16 shown in FIG. 1, but is the snap-on connection type that makes contact so as to achieve an effective conductive connection state within a predetermined range in the axial direction.

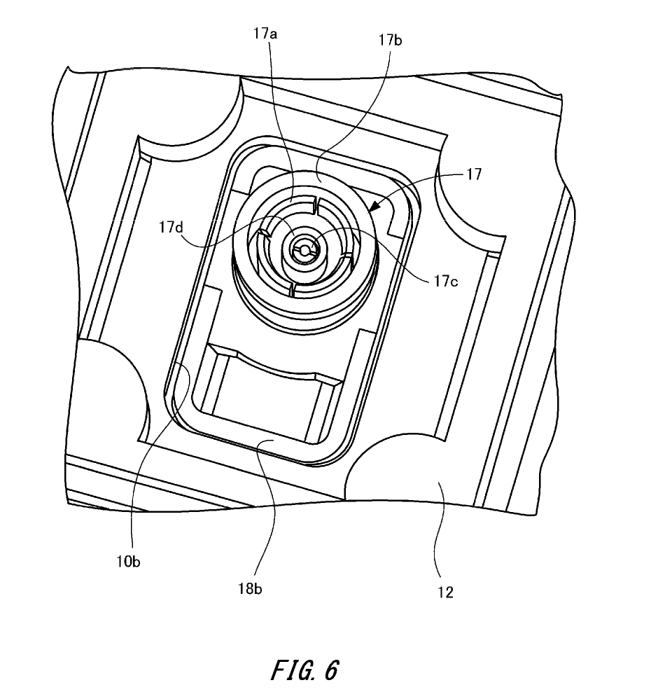

The second connection terminal 17 is not described in detail herein as the second connection terminal 17 may be similar to that of a conventional SMB type. For example, as illustrated in FIG. 6, the second connection terminal 17 has a tubular outer contact 17a that has a plurality of engagement claws and engages with an outer peripheral surface of the first connection terminal 16 in a snap-on manner, and a conductive tubular shell 17b, which is connected to the outer contact 17a in a conductive state. Further, although a detailed structure of the second connection terminal 17 is not illustrated in the drawings, the second connection terminal 17, for example, has an tubular inner contact 17c that has a plurality of slits and contact claw portions and makes contact with an outer peripheral surface of the central conductor 25a of the receptacle 25 with a predetermined contact pressure, and a tubular insulator 17d that surrounds a main portion of the inner contact 17c.

As illustrated in FIG. 1 and FIG. 6, the lid-shaped body 18 is a molded resin product that retains the second connection terminal 17 so as to integrally embed a main portion of the second connection terminal 17 and one end portion of the connection cable 2 in advance. For example, the lid-shaped body 18 has a smooth surface on a front side thereof and has fine irregularities formed by surface texturing, etc. on a rear-side surface thereof. The lid-shaped body 18 is formed in a lid-like shape that closes the opening 10b of the case 10.

As illustrated in FIG. 7, the connection cable 2, the second connection terminal 17, and the lid-shaped body 18 constitute an integrated connector cable 20 as a whole. Further, the shell 17b of the second connection terminal 17 is brazed or crimp-connected to an outer conductor of the connection cable 2 at an end portion on the connection cable 2 side, the outer conductor not being illustrated in the drawings. The outer conductor of the connection cable 2 is a publicly known mesh wire, for example. The outer contact 17a of the second connection terminal 17 is arranged to be conductive to the outer conductor of the connection cable 2 side via the shell 17b and to be grounded (connected to the ground) via the connection cable 2.

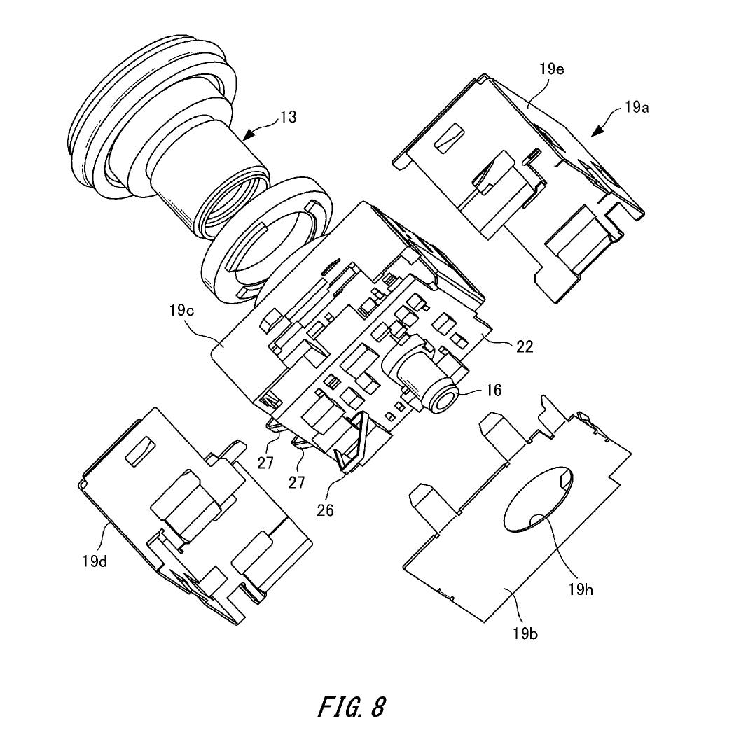

As illustrated in FIG. 1 and FIG. 8, the shielding case 19 is provided around the electronic circuit unit 15 inside the case 10, while being formed in a box-like shape, and is accommodated inside the case 10 together with the electronic circuit unit 15 in a state that it surrounds the electronic circuit unit 15. Further, in a second case member 19b of the shielding case 19, a through hole 19h is formed through which the first connection terminal 16 passes.

The shielding case 19 has a first case member 19a and the second case member 19b. The first case member 19a has a bottomed concave shape so as to accommodate the first circuit board 21 and the second circuit board 22 of the electronic circuit unit 15. The second case member 19b, which has a lid-like shape, is fitted with the first case member 19a so as to close an opening end side of the first case member 19a and to be pressed against, and in contact with, the first case member 19a at many locations, and is brazed to the first case member 19a at many locations. Further, more specifically, as illustrated in FIG. 8, the first case member 19a is formed by assembling a pair of case sub-members 19d and 19e to both ends of a case main member 19c by brazing the case main member 19c, the case sub-member 19d, and the case sub-member 19e to one another. The case main member 19c is stamped and bent so as to have a bottom wall portion and at least a pair of side wall portions. The case sub-members 19d and 19e are bent so as to form a substantially sideways U-shaped cross section.

Both inner and outer peripheral surfaces of the substantially annular positioning member 24 are formed in a substantially cylindrical shape on one end side and on an inner peripheral surface side of the positioning member 24. On the one end side, the positioning member 24 is fitted with the rear end portion 13d of the imaging optical unit 13. However, an outer peripheral surface on the other end side of the positioning member 24 is formed in a substantially square shape so as to abut against an inner bottom wall surface and side wall surfaces (no reference numerals are assigned to any of these) of the first case member 19a of the shielding case 19, with the side wall surfaces surrounding the inner bottom wall surface. Further, an insulating support or an alternative part (neither of which are illustrated in the drawings) is interposed between the first circuit board 21 and the second circuit board 22, which are supported on an upper surface of the positioning member 24, as illustrated in FIG. 1.

Further, as illustrated in FIG. 8, an elastic member 26, which has a plate spring shape, or the like is interposed between the second circuit board 22 and a ceiling surface of the second case member 19b of the shielding case 19 so as to inhibit mutual interference. A plurality of elastic members 27, which have a plate spring shape, are interposed between the first circuit board 21 and the front case 11. The plurality of elastic members 27 are supported by the first circuit board 21 and protrude from the shielding case 19 to the front case 11 side. In addition, a plurality of elastic members are mounted on one of the first circuit board 21 and the shielding case 19, the plurality of elastic members protruding from the shielding case 19 to the front case 11 side in a similar manner to that of the elastic members 27. The first circuit board 21 and the shielding case 19 are engaged with the front case 11 with a predetermined contact pressure via the elastic members 27, etc. in four directions including the right and left directions and directions perpendicular to the paper surface direction in FIG. 1.

Then, the shielding case 19, which accommodates the electronic circuit unit 15, the positioning member 24, etc., is fixed inside the front case 11 in a state where it is integrated with the imaging optical unit 13, as described above.

The outer contact 17a and the shell 17b of the second connection terminal 17 are formed in a tubular shape and are separated from the first connection terminal 16 on an outer side in a radial direction thereof, the first connection terminal 16 being the outer conductor on the receptacle side. The outer contact 17a and the shell 17b each have an inner diameter that is larger than an outer diameter of the first connection terminal 16. The outer contact 17a and the shell 17b constitute an outer conductor of the second connection terminal 17.

The imaging device main body 1 further includes a fixing mechanism 35 that fixes the lid-shaped body 18 to the case 10 in a state wherein the opening 10b of the case 10 is closed by the lid-shaped body 18.

As illustrated in FIG. 2 to FIG. 5B, the fixing mechanism 35 is configured to include: a plurality of female screw holes 10f (female screw portions) that are formed in the case 10, for example, at four locations; a substantially U-shaped sheet metal bracket 36 that is formed by integrating a plurality of washer-shaped portions 36a corresponding to the plurality of female screw hole portions 10f; fastening and fixing portions 18a that each have a U-shape (a concave shape opening outwardly) and are formed around the lid-shaped body 18 at positions corresponding to the plurality of female screw hole portions 10f; an elastic sealing ring 32 that is interposed between the opening 10b of the case 10 and the lid-shaped body 18; and a plurality of male screw members 37 (fastening members or male screws) that are screwed to the plurality of female screw hole portions 10f.

The bracket 36 is a member that can apply a pressing force so as to press the lid-shaped body 18 against the case 10. The bracket 36 is fastened and fixed to the case 10 by the plurality of male screw members 37. To the bracket 36, a pair of mounting plate portions 36b are integrally provided. The pair of mounting plate portions 36b have mounting holes, for example, female screw holes (no reference numerals are assigned to these), so that the imaging device main body 1 is supported by a support member on a vehicle side.

More specifically, when the lid-shaped body 18 abuts against the case 10 so as to close the opening 10b of the case 10, this can cause the second connection terminal 17 to be connected to the first connection terminal 16. The fixing mechanism 35 is configured to fix the lid-shaped body 18 to the case 10 in a state in which the opening 10b of the case 10 is closed by the lid-shaped body 18.

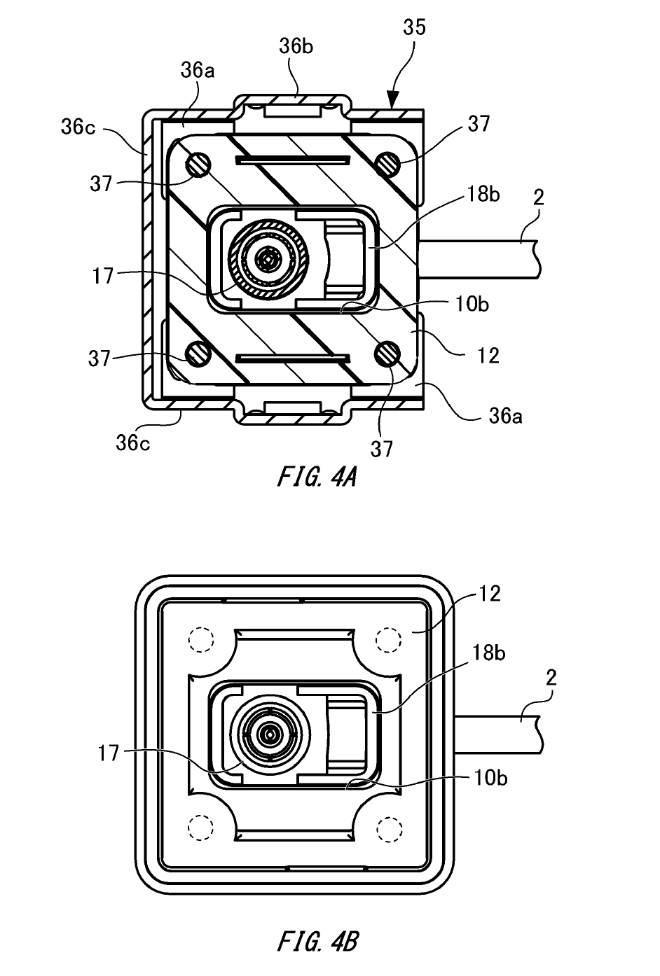

Further, the lid-shaped body 18 has a smooth abutting surface S that abuts against an upper surface 10c (refer to FIGS. 5A and 5B) of the case 10. The lid-shaped body 18 is movable with respect to the case 10 in a direction of the abutting surface S (an abutting surface direction) that is substantially orthogonal to a direction of center axes of the first connection terminal 16 and the second connection terminal 17. Further, the lid-shaped body 18 has a substantially rectangular loose-fitting convex portion 18b that is loose-fitted inside the opening 10b of the case 10 allowing for play of the convex portion 18b inside the opening 10b within a predetermined movable range (refer to FIG. 4A and FIG. 4B).

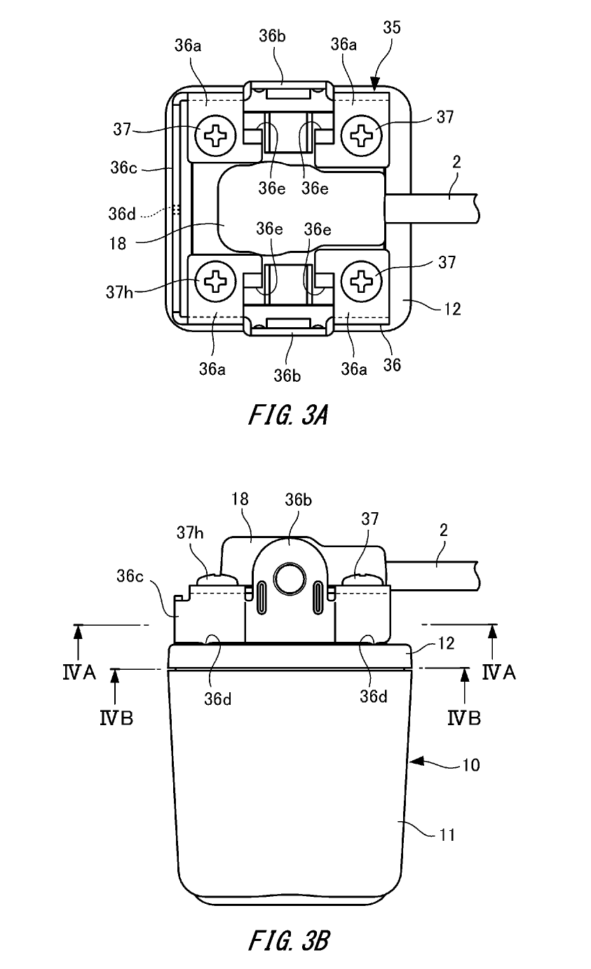

As illustrated in FIG. 2, FIG. 3A, and FIG. 3B, the bracket 36 has a substantially U-shaped bracket main body 36c, which is loose-fitted so as to be movable with respect to the lid-shaped body 18 in the abutting surface direction S, and a plurality of protruding portions 36d, which are pressed against, and in contact with, the case 10 so as to each locally penetrate into the case 10 when the bracket 36 is fastened and fixed to the case 10 by the male screw members 37.

Then, the plurality of protruding portions 36d formed on a top end side of the bracket main body 36c of the bracket 36 are pressed against, and in contact with, the case 10 so as to penetrate into the case 10 during a period when the bracket 36 is being fastened to the case 10 by the male screw members 37. Thereby, the bracket 36 is fixed at an arbitrary position within the movable range with respect to the case 10 in the abutting surface direction S.

The plurality of washer-shaped portions 36a of the bracket 36 are integrally formed with the substantially U-shaped bracket main body 36c and are bent, in a direction that causes them to approach to each other, from both arm portions of the bracket main body 36c, which are substantially in parallel to each other. When the plurality of washer-shaped portions 36a are pressed in a fastening direction by head portions 37h of the male screw members 37, the washer-shaped portions 36a can fix the fastening and fixing portions 18a of the lid-shaped body 18 by clamping the fastening and fixing portions 18a against the case 10 in conjunction with the male screw members 37.

Each of the plurality of protruding portions 36d of the bracket 36 is formed in a spike shape as a part of a punched shape of a sheet metal that forms the bracket 36, for example. The plurality of protruding portions 36d are respectively arranged in three directions (on the upper side, lower sided and left side in FIG. 3A) in which the substantially U-shaped bracket main body 36c covers the lid-shaped body 18. Thus, top ends of the plurality of protruding portions 36d each have a ridge line extending in a sheet thickness direction and the plurality of protruding portions 36d are partially arranged orthogonally so that ridge lines of the top ends thereof are orthogonal to each other (refer to FIG. 3A and FIG. 3B).

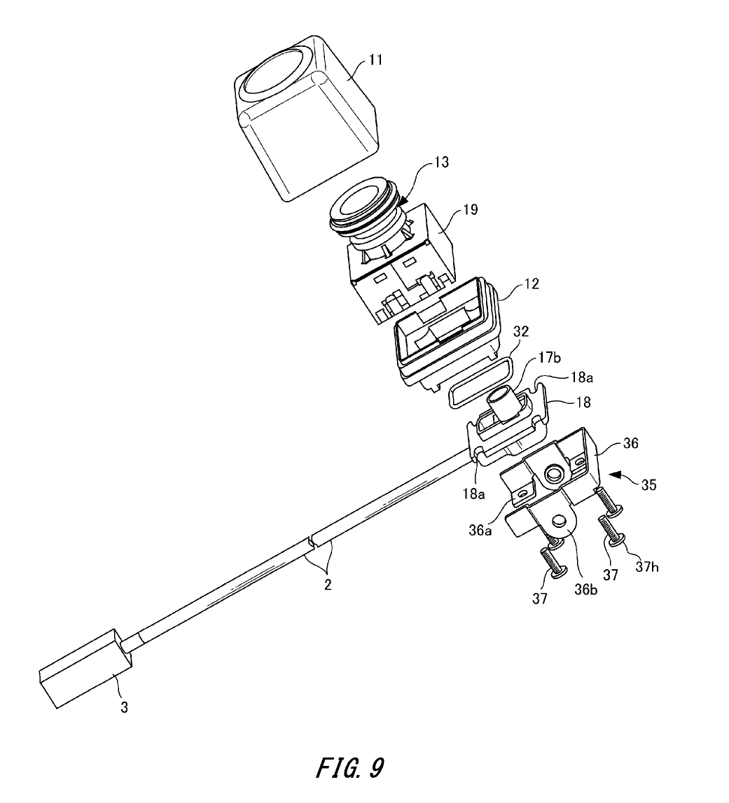

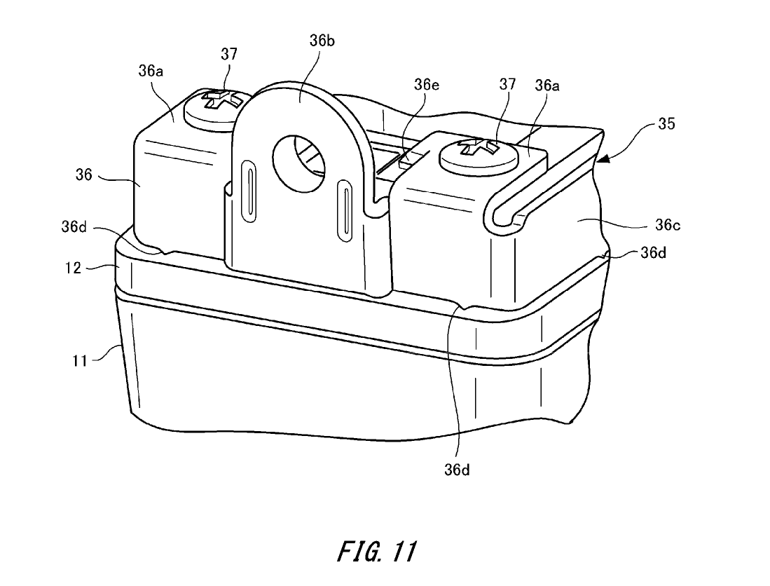

The male screw members 37 are a plurality of fastening members that are screwed to the plurality of female screw hole portions 10f that are provided in the case 10. Then, the plurality of washer-shaped portions 36a are bent on a rear end side of the bracket main body 36c in a direction orthogonal to the bracket main body 36c so that the male screw members 37 penetrate therethrough (refer to FIG. 9 and FIG. 11).

Further, the bracket 36 has a plurality of local pressure contact portions 36e on closer end sides of each of a pair of the adjacent washer-shaped portions 36a. The plurality of local pressure contact portions 36e are locally pressed against, and in contact with, the lid-shaped body 18 when the bracket 36 is fastened and fixed to the case 10 by the male screw members 37. Note that, although here each of the plurality of local pressure contact portions 36e is formed in an edge portion on one surface on a top end side of a bent portion that is provided so as to be continuous with the plurality of washer-shaped portions 36a, a shape of the local pressure contact portion 36e can take any shape as long as the local pressure contact is possible.

A distance in a height direction between a top end of each of the plurality of protruding portions 36d of the bracket 36 and each of the local pressure contact portions 36e of the bracket 36 is set so that the plurality of local pressure contact portions 36e are pressed against, and in contact with, the lid-shaped body 18 after the protruding portions 36d of the bracket 36 are pressed against, and in contact with, the case 10 by a contact pressure equal to or greater than a predetermined contact pressure and a state is obtained in which the bracket 36 is substantially fixed to the case 10 in the abutting surface direction S.

Next, effects will be described.

In the imaging device according to this embodiment having the above-described configuration, when the lid-like body 18 is caused to approach the case 10, which accommodates the electronic circuit unit 15, so as to close the opening 10b, the loose-fitting convex portion 18b of the lid-like body 18 is loose-fitted inside the opening 10b, and the second connection terminal 17 is thus fitted with the first connection terminal 16 in a male-female manner.

At that time, the lid-shaped body 18, which is movable with respect to the case 10 in the abutting surface direction S, and the second connection terminal 17 are positioned in the abutting surface direction S so as to obtain a state in which the second connection terminal 17 has a good conductive contact with the first connection terminal 16 that is accommodated in the case 10. In other words, a state is obtained in which a connection is made between the first connection terminal 16 and the second connection terminal 17 with their respective center axes aligned with each other. Note that a state in which the first connection terminal 16 and the second connection terminal 17 are connected to each other with their respective center axes aligned with each other is a state in which the best impedance characteristics of the connected portion are achieved, and in that state, an image transmission signal can also be transmitted most efficiently.

The bracket 36 of the fixing mechanism 35 is fastened and fixed to the case 10 by the male screw members 37 in a state where it is able to apply a pressing force so as to press the lid-shaped body 18 against the case 10.

When the male screw members 37 are fastened, the plurality of protruding portions 36d of the bracket 36 are locally pressed against, and in contact with, the case 10 so as to each penetrate into the case 10. As a result of this, the bracket 36 is fixed at an arbitrary position within the movable range with respect to the case 10 in the abutting surface direction S.

Therefore, when the bracket 36 is fastened and fixed, it becomes difficult for the bracket 36 to be horizontally displaced or rotated with respect to the case 10, and only the pressing force, which presses the lid-shaped body 18 against the case 10, is effectively transmitted from the bracket 36 to the lid-shaped body 18. Thus, obstruction of a good contact state of the second connection terminal 17 to the first connection terminal 16 as a result of horizontal displacement of the lid-shaped body 18 is effectively removed.

As a result, a small and high performance imaging device is obtained that is capable of efficiently transmitting an image transmission signal without loss relating to an external radio wave or noise.

Further, in this embodiment, the first connection terminal 16 and the second connection terminal 17 are formed by the male and female conductors of the coaxial cable, respectively. Thus, it becomes possible to efficiently transmit an image transmission signal without loss relating to an external radio wave or noise, even when the image transmission signal has a high frequency.

Further, in this embodiment, when the bracket 36 is fastened and fixed to the case 10 by the male screw members 37, the plurality of local pressure contact portions 36e of the bracket 36 are each locally pressed against, and in contact with, the lid-shaped body 18. Thus, the lid-shaped body 18 is reliably fixed at an arbitrary position within the movable range in the abutting surface direction S. Further, after the plurality of protruding portions 36d of the bracket 36 are pressed against, and in contact with, the case 10 by a surface pressure equal to or greater than a predetermined surface pressure and the bracket 36 is substantially fixed in the abutting surface direction S, the local pressure contact portions 36e of the bracket 36 are pressed against, and in contact with, the lid-shaped body 18 in the fastening direction. Therefore, when the bracket 36 is fastened and fixed, it becomes difficult for the bracket 36 to be horizontally displaced or rotated with respect to the case 10, and only the pressing force, which presses the lid-shaped body 18 against the case 10, is effectively transmitted from the bracket 36 to the lid-shaped body 18.

In addition, in this embodiment, the male screw members 37 are constituted by the plurality of male screws that are screwed to the plurality of female screw portions provided in the case 10, and the bracket 36 has the plurality of washer-shaped portions 36a through which the male screw members 37 penetrate. Thus, it becomes difficult for the bracket 36 to be horizontally displaced or rotated due to the fastening operation of the respective male screw members 37. As a result, obstruction of a good contact state of the second connection terminal 17 with respect to the first connection terminal 16 as a result of horizontal displacement of the bracket 36 is effectively removed.

In this manner, according to this embodiment, when the lid-shaped body 18 is fastened by the male screw members 37 via the bracket 36, the plurality of protruding portions 36d of the bracket 36 are locally pressed against, and in contact with, the case 10 so as to each penetrate into the case 10. Accordingly, obstruction of a good contact state of the second connection terminal 17 with respect to the first connection terminal 16 as a result of horizontal displacement of the bracket 36 is effectively removed. Therefore, the lid-shaped body 18 is reliably fixed at an arbitrary position within the movable range in the abutting surface direction S, and a small and high performance imaging device can be provided that is capable of efficiently transmitting an image transmission signal without loss relating to an external radio wave or noise, even when the image transmission signal has a high frequency.

Note that, in the above-described embodiment, although the bracket 36 has a substantial U-shape that covers a periphery of the lid-shaped body 18 from three directions, the bracket 36 may have a different shape. For example, the bracket 36 may have a shape that covers the periphery of the lid-shaped body 18 from two directions and connects the washer-shaped portions 36a with each other on a rear side of the lid-shaped body 18. Further, in the above-described embodiment, although each of the plurality of protruding portions 36d is formed in a spike shape as a part of the punched shape of the sheet metal, it goes without saying that the protruding portions may be formed through plastic deformation by a process other than the punching process. Further, it is preferable that the fixing mechanism be able to fix the lid-shaped body 18 to the case 10 at an arbitrary position in the abutting surface direction by using a bracket with spikes, etc. as described in the above-described embodiment. However, for example, when a fixing mechanism is configured such that the lid-shaped body 18 is adhered or welded to the rear case 12 of the case 10 in a state in which the first connection terminal 16 and the second connection terminal 17 have a good connection, a bracket without spikes may be used or the bracket may be omitted. Further, it goes without saying that, in place of the fixing mechanism that is formed by the bracket with spikes and the fastening member, any fixing mechanism can be used as long as it is interposed between the case 10 and the lid-shaped body 18 and can fix the case 10 and the lid-shaped body 18 in a state in which both the case 10 and the lid-shaped body 18 are positioned with respect to each other.

Further, in the above-described embodiment, although SMB connectors or similar non-snap-lock type coaxial connectors with a small diameter are used as the first connection terminal 16 and the second connection terminal 17, coaxial connectors of another type may be used. Further, the male and female connector members may be formed not only by the connector members, such as the first connection terminal 16 and the second connection terminal 17 that each have respective single internal conductors, namely, the central conductor 25a and the inner contact 17c, but also by connector members having a plurality of internal conductors.

As described above, the present invention can provide a small and high performance imaging device that is capable of efficiently transmitting an image transmission signal without loss relating to an external radio wave or noise. The present invention is useful as an imaging device in general and is particularly suitable for an in-vehicle camera, etc.

### REFERENCE SIGNS LIST

1 imaging device main body
2 connection cable (coaxial cable)
3 connector
10 case
10a concave portion
10b opening
10c upper surface
10f female screw hole (female screw portion)
11 front case
11a taper hole
12 rear case
13 imaging optical unit
13a top end portion
13b O-ring
13c installation ring
13d rear end portion
14 imaging element
15 electronic circuit unit
16 first connection terminal
16a taper portion
16b straight portion
17 second connection terminal
17a outer contact
17b shell
17c inner contact
17d insulator
18 lid-shaped body
18a fastening and fixing portion
18b loose-fitting convex portion
19 shielding case
19a first case member
19b second case member
19c case main member
19d, 19e case sub-member
19h through hole
20 connector cable
21 first circuit board
22 second circuit board
23 FPC (Flexible Printed Circuit)
24 positioning member
25 receptacle
25a central conductor
25b insulator
26 elastic member
27 elastic member
32 elastic sealing ring
35 fixing mechanism
36 bracket
36a washer-shaped portion
36b mounting plate portion
36c bracket main body
36d protruding portion (spike portion)
36e local pressure contact portion
37 male screw member (fastening member, male screw)
37h head portion

1. An imaging device comprising:
an electronic circuit unit that includes an imaging element and a first connection terminal;
a case that has a concave portion for accommodating the electronic circuit unit and an opening for allowing the first connection terminal to be exposed therefrom;
a lid-shaped body that is formed in a lid-like shape so as to close the opening, the lid-shaped body integrally retaining a second connection terminal that is to be connected to the first connection terminal and causing the second connection terminal to be connected to the first connection terminal when the lid-shaped body abuts against the case so as to close the opening; and
a fixing mechanism that fixes the lid-shaped body to the case in a state in which the opening is closed by the lid-shaped body, wherein
the lid-shaped body is loose-fitted in a movable manner to the case in a direction of an abutting surface that is substantially orthogonal to center axes of the first connection terminal and the second connection terminal, and
the lid-shaped body is fixed at an arbitrary position within a movable range with respect to the case in the abutting surface direction in a state in which the center axes of the first connection terminal and the second connection terminal are substantially aligned with each other.

2. The imaging device according to claim 1, wherein the first connection terminal and the second connection terminal are formed by male and female conductors of a coaxial connector, respectively.

3. The imaging device according to claim 1, wherein
the fixing mechanism includes a bracket that can apply a pressing force so as to press the lid-shaped body against the case and a fastening member that fastens and fixes the bracket to the case, and
the bracket has a plurality of protruding portions that are locally pressed against, and in contact with, the case when the bracket is fastened and fixed to the case by the fastening member.

4. The imaging device according to claim 3, wherein the bracket includes a bracket main body that is loose-fitted in a movable manner with respect to the lid-shaped body in the abutting surface direction and a plurality of local pressure contact portions that are locally pressed against, and in contact with, the lid-shaped body when the bracket is fastened and fixed to the case by the fastening member.

5. The imaging device according to claim 3, wherein
the fastening member is formed by a plurality of male screws that are screwed to a plurality of female screw portions provided in the case, and
the bracket has a plurality of washer-shaped portions through which the male screws penetrate.
